(19) United States
(12) Patent Application Publication
(10) Pub. No.: US 2023/0231357 A1
(43) Pub. Date: Jul. 20, 2023

(54) Scalable Visible Brillouin Fiber Laser

(71) Applicant: Nuburu, Inc., Centennial, CO (US)

(72) Inventors: Mark S. Zediker, Castle Rock, CO (US); Adam Paricio-Moreau, Littleton, CO (US); Marin Iliev, Littleton, CO (US)

(73) Assignee: Nuburu, Inc., Centennial, CO (US)

(21) Appl. No.: 18/083,520

(22) Filed: Dec. 17, 2022

Related U.S. Application Data
(60) Provisional application No. 63/291,238, filed on Dec. 17, 2021.

(51) Int. Cl. H01S 3/30; H01S 3/0941; H01S 3/067

(52) U.S. Cl. CPC H01S 3/302; H01S 3/0941; H01S 3/0675

(57) ABSTRACT

There are provided methods and system for providing high power, high brightness, visible laser source and laser beams. There are provided methods and systems of a direct conversion of poor beam quality visible laser light sources into a single high brightness beam in a resonant or ring laser cavity using a dual core or single core optical fiber and Stimulated Brillouin Scattering as the non-linear conversion mechanism in the graded index core of the fiber.

This application claims the benefit of priority to, and under 35 U.S.C. § 119(e)(1) the benefit of the filing date of, U.S. provisional application Ser. No. 63/291,238, filed Dec. 17, 2021, the entire disclosure of which is incorporated herein by reference.

### BACKGROUND OF THE INVENTION

### Field of the Invention

The present inventions relate to high power visible lasers, and in particular, high power blue lasers.

The ability to produce a very high power, single mode visible laser source is currently limited to using an infrared laser that is wavelength converted by a non-linear crystal. This technology has several drawbacks and long-standing problems. Among these, are that the output power of this device is limited by the quality of the non-linear crystal and the power density of the Infrared light source. Additionally, in order to achieve high efficiency in the non-linear conversion process, the infrared light is often injected into a resonant cavity where the frequency of the pump and the impedance of the resonance cavity have to be matched to the desired output wavelength and losses in the resonant cavity, increasing complexity and reducing reliability. These, and other drawbacks and problems, have made high power, single mode visible laser sources difficult to scale to high power levels.

Embodiments of the present inventions overcome these and other long-standing problems with high power, single mode visible laser sources and laser beams. These embodiments of the invention do not have these limitations associated with prior lasers and beams, because, among other reasons, embodiments of the present inventions provide for a direct conversion of poor multi-mode visible laser light sources into a single mode beam in a resonant laser cavity, a ring laser cavity, or a Master Oscillator Power Amplifier laser system. Stimulated Brillouin Scattering is the non-linear conversion mechanism in the core of the fiber that converts the low brightness pump lasers to a single mode or near single mode beam.

As used herein, unless expressly stated otherwise, the terms “visible”, “visible spectrum”, and “visible portion of the spectrum” and similar terms, should be given their broadest meaning, and would include light in the wavelengths of from about 380 nm to about 750 nm, and 400 nm to 700 nm.

As used herein, unless expressly stated otherwise, “UV”, “ultra violet”, “UV spectrum”, and “UV portion of the spectrum” and similar terms, should be given their broadest meaning, and would include light in the wavelengths of from about 10 nm to about 400 nm, and from 10 nm to 400 nm, and all wavelengths coming within these ranges.

As used herein, unless expressly stated otherwise, the terms “laser diode”, “diode emitter”, “laser diode bar”, “laser diode chip”, and “emitter” and similar such terms are to be given their broadest meaning. Generally, the laser diodes is a semiconductor device that emits a laser beam, such devices are commonly referred to as edge emitting laser diodes because the laser light is emitted from the edge of the substrate. Typically, diode Lasers with a single emission region (Emitter) are typically called laser diode chips, while a linear array of emitters is called laser diode bars. The area emitting the laser beam is referred to as the “facet.”

As used herein, unless expressly stated otherwise, the terms “high power”, “high power lasers”, “high power beams” and “high power laser beams” and similar such terms, mean and include laser beams, devices and systems that provide or propagate laser beams that have at least 10 Watts (W) of power as well as greater powers, at least 100 W and greater, for example from 10 Watts to 10 kW (kilowatts), form 100 W to 100 kW, from 50 W to 1 kW, from about 100 W to about 1 kW, from 400 W to 5 KW, from 500 W to 20 kW, from 500 W to 10 kW, from about 500 W to about 5 kW, from 1 kW to 10 kW, from 1 kW to 20 kW, from about 10 kW to about 40 kW, from about 5 kW to about 100 kW, and all powers within these ranges, as well as higher powers.

As used herein, unless expressly stated otherwise, the terms “blue laser beams”, “blue lasers” and “blue” should be given their broadest meaning, and in general refer to systems that provide laser beams, laser beams, laser sources, e.g., lasers and diodes lasers, that provide, e.g., propagate, a laser beam, or light having a wavelength from about 400 nm to about 495 nm, from 400 nm to 495 nm, and all wavelengths within these ranges. Typical blue lasers have wavelengths in the range of about 405-495 nm. Blue lasers include wavelengths of 450 nm, of about 450 nm, of 460 nm, of about 470 nm, and from 440 nm to 470 nm. Blue lasers can have bandwidths of from about 100 Hz to about 10 pm (picometer) about 10 nm, about 5 nm, about 10 nm and about 20 nm, as well as greater and smaller values.

As used herein, unless expressly stated otherwise, the terms “high reliability”, “highly reliable”, lasers and laser systems and similar terms, mean and include lasers which have a lifetime of at least 10,000 hours or greater, about 20,000 hrs, about 50,000 hours, about 100,000 hours, from about 10 hours to about 100,000 hours, from 10,000 to 20,000 hours, from 10,000 hours to 50,000 hours, from 20,000 hours to about 40,000 hours, from about 30,000 hours to about 100,000 hours and all values within these ranges.

As used herein, unless expressly stated otherwise, the terms “lifetime”, “system lifetime, and “extended lifetime” and similar such terms, are defined as the time during which the output power, other properties, and both of the laser stay at or near a percentage of its nominal value (“nominal value” is the greater of (i) the laser's rated power, other properties, and both, as defined or calculated by the manufacturer, or (ii) the initial power, other properties, and both, of the laser upon first use, after all calibrations and adjustments have been performed). Thus, for example, an “80% laser lifetime” is defined as the total operating time when the laser power, other properties, and both remains at 80% of the nominal value. For example, a “50% laser lifetime” is defined as the total operating time when the laser power, other properties, and both remains at 50% of the nominal value. As used herein, unless specified otherwise or otherwise clear from the context, the term “lifetime” as used herein is referring to an “80% life time”.

Generally, the term “about” and the symbol “—” as used herein, unless specified otherwise, is meant to encompass the larger of a variance or range of ±10% or the experimental or instrument error associated with obtaining the stated value.

As used herein, unless expressly stated otherwise, terms such as “at least”, “greater than”, also mean “not less than”, i.e., such terms exclude lower values unless expressly stated otherwise.

As used herein, unless stated otherwise, room temperature is 25° C. And, standard temperature and pressure is 25° C. and 1 atmosphere. Unless expressly stated otherwise all tests, test results, physical properties, and values that are temperature dependent, pressure dependent, or both, are provided at standard temperature and pressure.

As used herein, unless specified otherwise, the recitation of ranges of values, a range, from about “x” to about “y”, and similar such terms and quantifications, serve as merely shorthand methods of referring individually to separate values within the range. Thus, they include each item, feature, value, amount or quantity falling within that range. As used herein, unless specified otherwise, each and all individual points within a range are incorporated into this specification, and are a part of this specification, as if they were individually recited herein.

This Background of the Invention section is intended to introduce various aspects of the art, which may be associated with embodiments of the present inventions. Thus, the foregoing discussion in this section provides a framework for better understanding the present inventions, and is not to be viewed as an admission of prior art.

### SUMMARY

There remains a continued, important and significant need for more reliable, better and economical ways to provide high power, single mode visible laser source and to further provide very high power, single mode visible laser source. The present inventions, among other things, solve these needs by providing the articles of manufacture, devices and processes taught, and disclosed herein.

Thus, in an embodiment the invention consists of multiple narrow linewidth (<10 MHz) visible laser diodes where the laser beams from these laser diodes are injected into an optical fiber that uses the Stimulated Brillouin Scattering (“SBS”) non-linear phenomenon to provide gain in the laser medium. This Brillouin gain in the optical fiber converts the low brightness multi-mode laser input beams into a low order modes or a single high brightness mode in the graded index core of the optical fiber. The conversion occurs because the LP₀₁ mode has the lowest loss of any mode propagating in the core and as consequence experiences the greatest gain and becomes the preferred oscillating mode. The narrow linewidth, high power visible laser sources can be created by injection locking, coherent combination, and simultaneously locking a group of visible lasers in an external cavity with a narrow bandwidth filter in the cavity or as the mirror such as a Volume Bragg Grating (VBG). The preferred embodiment is to use a master oscillator to injection lock a group of visible laser diodes or laser diode bar. The master oscillator operates at a linewidth narrower than the Stimulate Brillouin gain linewidth of the medium, where the linewidth requirements of some exemplary various bulk materials and fiber materials are listed in Tables 1 and 2. A narrow linewidth visible laser diode is achieved with a single transverse mode visible laser diode that is restricted to oscillate on a single axial mode of the laser cavity. A single axial mode operation of a laser diode can be achieved by suppressing the other axial modes of the laser diode. The preferred embodiment is to use a laser diode with an anti-reflection coated output facet in an external cavity with a filter that allows only one axial mode to oscillate. The filter can be an etalon, a grating used in Littrow, a VBG, an external cavity with a series of etalons, or any other method to suppress the closely spaced longitudinal modes of the laser cavity. Groups of laser diodes can be locked in an external cavity with a filter to suppress both longitudinal and transverse modes in a simple external cavity with a spatial filter, or a Talbot cavity which relies on the coherent interference at each Talbot cavity to create a common single supermode for the group of laser diodes. Once isolate, the single axial mode of the master oscillator may not be sufficiently stable to achieve the narrow linewidths required for the pump. The master oscillator and cavity components must be mounted in a very stable mechanical assembly, the entire assembly must be temperature controlled to a few milli-K, and the current that drives the laser diode must be driven by a low noise power supply typically a few μAamps to <10 nAmps.

A SBS visible wavelength laser system, the system comprising: a first assembly comprising a plurality of laser diodes, and a beam integration system, whereby the first assembly is configured to provide a first laser beam; second assembly comprising a first port for receiving the first laser beam from the first assembly, a second port, a third port and a fourth port; a optical fiber resonator comprising a medium, a graded index core, and configured to provide a Brillion gain; wherein a first end of the optical fiber is associated the second port and a second end of the optical fiber is associate with the third port; whereby the first end of the optical fiber receives the first laser beam in a forward propagating direction; whereby the optical fiber is configured to generate and propagate an SBS laser beam in a backward direction within the optical fiber resonator, thereby providing a backward propagating SBS laser beam; and whereby the optical fiber is configured to propagate an undepleted first laser beam in the forward direction; the second end of the optical fiber configured to propagate the underplated first laser beam to port three of the second assembly; port three of the second assembly configured to propagate the backward propagating SBS laser beam into the second end of the optical fiber resonator, out of the system as an output beam, or both; the fourth port configured to prorogate the undepelated first laser beam out of the system.

There is future provided these laser systems or methods having one or more the following features: wherein the first laser beam has a wavelength in the blue wavelength range and an input BPP; the output laser beam has a wavelength in the blue wavelength range and an output BPP, wherein the output BPP improved over the input BBP by from 10× to 400×; wherein the first assembly comprises a BAL; the second assembly comprises a Faraday rotator, a half wave plate and an HR mirror; wherein the output laser beam is a single mode beam.

Still further there is provided a visible wavelength SBS laser pumped by visible laser diodes that operates at a wavelength between 380 nm and 700 nm.

Moreover, there is provided these lasers, systems and methods, having one or more of the following features: the laser is pumped by multi-transverse or single transverse mode laser diodes or diode bar(s) with wavelengths between 380 nm and 700 nm; the laser produces a low M² beam of 1 to 2, 2 to 3 but less than 10; that uses a phosphorous doped graded index fiber that supports many modes as well as an LP01 mode; that uses a phosphorous doped graded index fiber embedded in a step index core to enable low brightness laser sources to couple efficiently to the graded index core; that uses a polarization preserving phosphorous doped graded index core to increase the SBS gain of the fiber resonator and maintain polarization during oscillation; that uses a bulk SBS medium; that uses a circulator to extract the power from the resonator; that uses a circulator to redirect the power from the laser resonator; that uses an etalon to allow the pump beam to transmit into the cavity while forming a linear cavity for the SBS laser with the anti-node of the etalon; that uses embedded fiber Bragg gratings as the output coupler or the high reflector; that is wavelength broadened external to the cavity using an Acoustic Optic Modulator (AOM), an Electro-Optic Modulator (EOM), a pzt for stretching the fiber and causing phase modulation, or a vibrating mirror to phase modulate the beam such that the effective beam linewidth is broadened to allow transmission down a longer process fiber; that uses a special fiber for SBS compensation as a process fiber; that uses a fiber with periodic index variations longitudinally along the fiber to suppress the SBS in the process fiber; that uses a fiber with strain or periodic strain longitudinally along the fiber to suppress the SBS in the process fiber; that is coherently combined with an ensemble of similar SBS lasers to form a single beam where (n>1) and the M² between 1 and 2, 2 and 3 but less than 10; that is incoherently combined with an ensemble of similar SBS lasers using spatial or polarization or spatial and polarization combination methods where n>1; that is combined using dichroic filters to overlap an ensemble of SBS laser beam to achieve a higher power level than 1 laser while maintaining the beam quality of the individual SBS laser; that is combined using VBGs to overlap an ensemble of SBS laser beams to achieve a higher power level while maintaining beam quality of the individual SBS laser; that is combined using gratings to overlap an ensemble of SBS laser beams to achieve a higher power level while maintaining beam quality of the individual SBS laser in claim 5; that is combined using a Lyot filter to overlap an ensemble of SBS laser beams to achieve a higher power level while maintaining beam quality of the individual SBS laser; wherein the linewidth of the laser diode pumps are narrowed by injection locking from a common Master Oscillator source; wherein the linewidth of the laser diode pumps that are narrowed by injection locking from a common Master Oscillator source that has been amplified by multiple broad area lasers where the multiple may be 1, 2 or more depending on the amount of power distributed to the pump laser diodes; wherein the laser diode pumps are narrowed by injection locking from multiple Master Oscillator sources that are mutually coherent; wherein the linewidth of the laser diode pumps are narrowed by using a common VBG as an external mirror for the ensemble of laser diodes where (n>1) wherein the linewidth of the laser diode pumps are narrowed by a common transmission grating in Littrow in an external cavity where (n>1); wherein the linewidth of the laser diode pumps are narrowed by a common reflection grating in Littrow where (n>1) wherein the linewidth of the laser diode pumps are narrowed by reflection grating in a Litman-Metcalf external cavity; wherein the linewidth of the laser diode pumps are narrowed by a common etalon or combination of etalons in an external cavity where (n>1); wherein the linewidth of the laser diode pumps of claim 6 are narrowed in a Talbot cavity using a mirror, VBG, grating, etalon or injection source; wherein the linewidth of the laser diode pumps of claim 6 are controlled by a precision current source with noise <10 nAmps; wherein the linewidth of the laser diode pumps in claim 6 is less than the SBS gain bandwidth of the media as listed in Table 1 and 2; and, wherein the linewidth of the laser diode pumps in claim 6 is less than the SBS gain bandwidth for a fused silica fiber which is 16 GHz.

There is still further the following applications and operations, wherein one or more of these lasers and systems is used for one or more of the following: is used for 3D printing all materials; is used for welding all materials; is used for projection display applications; is used for laser light shows; is used for medical applications; is used for 3D printing metals, plastics and other types of materials; is used with a scanner for remote welding and 3D printing; is used with a welding head for welding materials; is used with a blown powder head for 3D printing; is used with a wire feeder for 3D printing; is used with a powder bed for 3D printing; is used for laser communications; is used for underwater communications; is used for underwater lidar; is used for cutting underwater; and, is used for annealing semiconductor materials.

### BRIEF DESCRIPTION OF THE DRAWINGS

FIG. 1. Is a chart showing an embodiment of power vs mA for an embodiment of an injection locked visible laser in accordance with the present inventions.

FIG. 2 is a chart showing an embodiment of the free running spectrum of the laser diode and the injection locked spectrum of the laser diode in accordance with the present invention.

FIG. 3 is a chart of an embodiment of doping profile of the glass boule prior to pulling into a fiber in accordance with the present inventions.

FIG. 4 is a chart of an embodiment of loss measurements for an embodiment of a pulled fiber in accordance with the present inventions.

FIG. 5 is an example of how to improve the brightness of a laser diode bar using a beam twister and beam interdigitator/compressor in accordance with the present inventions.

FIG. 6. Is an example of a beam folder using polarization to decrease the effective width of the laser diode bar in accordance with the present inventions.

FIG. 7 is a schematic of an embodiment of a polarization insensitive circulator in accordance with the present inventions for injecting the pump source into the optical fiber and extracting the backward traveling Brillouin laser beam in accordance with the present inventions.

FIG. 8 is a schematic of an embodiment of the use of spectral combination of laser diodes or SBS lasers to pump a final SBS laser in accordance with the present inventions.

FIG. 9 is an embodiment of a master oscillator injection locking of a laser diode bar for creating a narrow linewidth source to pump the SBS laser in accordance with the present inventions.

FIG. 10 is a schematic of an embodiment of a Talbot plane in accordance with the present inventions in accordance with the present inventions.

### DESCRIPTION OF THE PREFERRED EMBODIMENTS

The present inventions relate to SBS lasers and systems, and in particular SBS lasers and systems operating in the visible light wavelength range, and in particular the blue light wavelength range.

Embodiments of the present inventions relate to high power, single mode visible lasers, high power multi-mode visible lasers and in particular high power, single mode blue lasers and high power multi-mode blue lasers.

In general embodiments of the present systems and lasers take a pump source laser beam from one or more pump laser sources, such as diode lasers operating in the visible and preferable the blue wavelength range. The pump laser beams are locked to a single axial mode, and injected into an assembly that separates the forward propagating pump light from the backward propagating laser beam created by the SBS phenomenon. This SBS light separation assembly can be for example a circulator. If a circulator is used the circulator can be either polarization dependent or polarization independent. The forward propagating light from the pump lasers enters the separation assembly at a first port, which can have, for example, a polarization beam splitter. The separation assembly has optical components, that function to provide a characteristic to the forward propagating light; and function to provide a different characteristic to the backward propagating light. After passing through these optical components of the separation assembly, the forward propagating light is directed out of the separation assembly at a second port, which can have, for example a polarization beam splitter. The forward propagating light is then coupled into the fiber, preferably by a lens assembly. The ends of this fiber may be, for example, prepared by a simple cleave, an AR coating on the fiber face, an angle cleave to reduce back-reflections or a glass block fused onto the fiber to decrease the power density on the input surface of the fiber. The forward pump power, from the forward light propagating into the fiber is converted in the fiber into light that is propagating backwards by the SBS phenomenon. For example, and preferably, the backward propagating SBS light is a single mode, single frequency light, however, it may also consist of many other transverse modes. The backward propagating SBS light enters the separation assembly, through a port, which can be the second port. The backward propagating SBS light is passed though the separation assembly, including its optical components, in the opposite direction than the forward propagating light passed through. In this manner, the forward and backward propagation light can then be separated, based upon their different characteristics imparted from the separation assembly. For example, the backward propagating light can be polarized and rotated, e.g., 90 degrees, from the forward propagating light by the separation assembly. Thus, the backward propagating light after passing through the optical components of the separation assembly, can exit the separation assembly by a port, for example the fourth port.

In embodiments the backward propagating light can be extracted from the separation assembly, reinjected into the fiber or both. If some of the backward propagating light is reinjected into the fiber, it can form a resonant ring cavity. Typically, undepleted pump light after passing through the fiber can be passed through the separation assembly and reject out of that assembly into a beam dump; or it can be directed into a beam dump without passing through the separation assembly. Thus, preventing the undepleted forward propagating pump light from recirculating in the ring cavity. The undepleted forward propagating light is generally a small amount of power in a Brillouin laser because the conversion process is very strong and the amount of pump depletion can be easily controlled by the length of the active medium, or fiber.

The Stimulated Brillouin laser beam can have powers that are up to >20%, >50%, >80% or >98% of the pump power in a single transverse mode beam because the wavelength shift is very small (10 GHz in fused silica) which is a very small quantum defect and as a consequence the conversion efficiency can be very high. This results in a substantial brightness enhancement of >10×, >100×, or >1000× or more depending upon the brightness of the pump laser source. In an embodiment, a bar of 20 or more individual laser diodes are injection locked and launched into the fiber. The laser diode bar has a beam parameter product (BPP) on the order of 30 mm-mrad or greater, while the single mode (e.g., single traverse mode), which is also preferably a single frequency, output beam (i.e., the backward prorogating SBS light) has a beam parameter product of 0.13 mm-mrad at 450 nm, which is an improvement of 230×. If multiple bars (2 or more, 5 or more, 10 or more) are used to pump the fiber, then this ratio can be substantially higher. In general, and by way of example, the beam parameter product of an injection locked input forward propagating pump laser beam, using the present systems, can provide an output beam for a particular wavelength (i.e., a backward propagating SBS laser beam) that has a 10× or more improvement in the BPP, 100× or more improvement in the BPP, a 200× or more improvement in the BPP, a 300× or more improvement in the BPP, 400× or more improvement in the BPP, from a 200× to a 500× improvement in the BPP, from a 200× to a 400× improvement in the BPP, as well as high and lower values. It being understood, that the lower the value of the BPP the higher or better the quality of the laser beam. Thus, improvements in BPP result in the lowering of that value. It is also noted the present inventions contemplate SBS layer systems that provide multi-mode output beams, and in which case the improvement in BPP will typically be in the range of 10× or more, 50× or more, and from about 10× to about 90× improvement.

In embodiments the systems can be scaled to provide much higher power Stimulated Brillion laser beams by addition of multiple high power pump lasers pumping the same fiber. Additionally, the system can be scaled by cascading multiple Brillion amplifiers. The difference between a resonator and an amplifier is the amplifier allows the beam to pass once through the gain medium, thus reducing the probability of a second order stokes wave from reaching threshold and causing a clamping of the first stokes wave. In addition, if a second stokes wave reaches threshold, chaotic operation of the laser can occur, so the length of the fibers should be selected to suppress the second stokes, use filters to dump the second stokes between amplifier stages, and use good quality AR coatings or angle cleaves on the ends of the fibers to prevent feedback to the second stokes wave, among other things. In embodiments where the fiber is phosphorous doped fused silica, and thus the laser media in which the SBS non-linear phenomenon is used to provide gain, is phosphorous doped fused silica, preferably In this embodiment, all of the pump sources are injection locked by the same master oscillator because of the extremely narrow gain bandwidth (10 MHz) of the Brillouin gain of the fused silica fiber medium.

Additionally, embodiments of the systems can be scaled by spectrally combining multiple but separate pump lasers launched into the same fiber to scale the output power of the single mode beam. Due to the narrow gain linewidth of the Stimulated Brillouin Scattering, multiple pump lasers spaced several gain linewidths apart, such as 1 nm or more can be launched into the optical fiber. Since each pump laser creates an independent or inhomogenously broadened gain spectrum, multiple SBS lasers sources can oscillate without interfering with each other. The output of the laser from these embodiments can then look much like a conventional laser, in that they have multiple longitudinal modes.

In embodiments, there is provided single transverse mode visible laser sources, which are commercially available are typically 100-150 mWatts of laser power. These laser sources can then be used to inject a Broad Area Laser (BAL) or laser diode bar which is a group of BALs and achieve very narrow (<10 MHz) single frequency operation of the BAL or laser diode bar. Under the right drive conditions for the BAL, current, temperature and injecting power, a high power 1-1.5 Watt single transverse mode beam can be extracted from the BAL with the linewidth of the master oscillator. While the single transverse mode is ideal for launching into a small diameter fiber, it is not a necessary requirement for pumping the SBS laser which uses a large graded index core or a graded index cored embedded in a step index core. However, it is preferable that the narrow linewidth is used to pump the SBS laser.

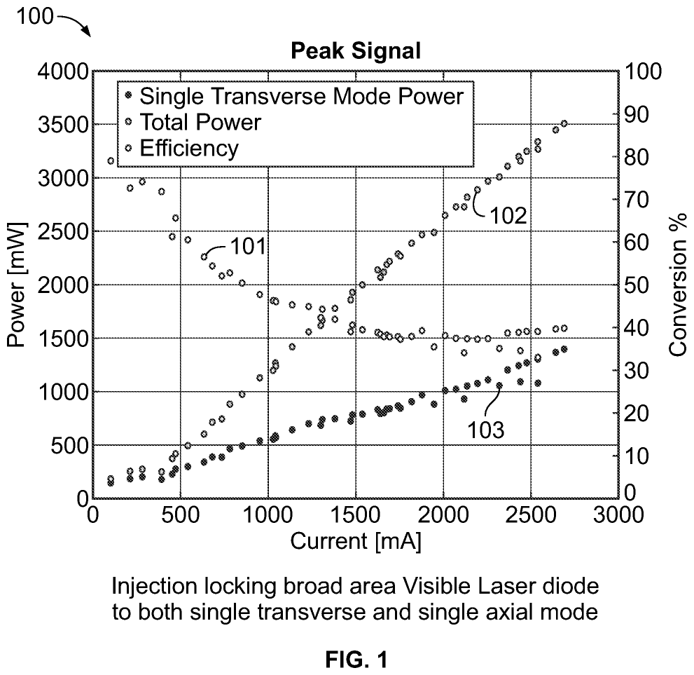

Thus, turning to FIG. 1 there is shown a graph 100 of the efficiency 101, the total power 102, and the single transverse mode power 103 of an injection locked BAL. The total power of the laser beam produced by the BAL consists of a multi-transverse mode output locked to a single axial mode 102 and the single transverse mode power 103. The fraction of the power of the BAL which is locked to the single transverse mode is 103. The efficiency of this lock in converting the multimode operation of the BAL to single mode operation is 101. In this embodiment the BAL is injection locked to produce both single transverse and a narrow (3 MHz) single axial mode.

The embodiment of FIG. 1, shows that up to 3 Watts of total power at a linewidth of 3 MHz can be extracted with only 25 mW of power injected from the narrow linewidth master oscillator. This total power is a combination of both a single transverse mode 103 and multiple transverse modes all locked to the 3 MHz linewidth of the master oscillator. This locking is achieved because in the normal operation of a laser, the modes build up from random optical noise in the cavity. Since this noise is a very low power level, it can be replaced by an external master oscillator signal which the laser will then build up from, or be injection locked. The injection locking process on a laser diode without an AR coating requires careful adjustment of the laser current to maintain full lock, however an AR coated laser diode will lock over a wide range stably without the need for an external locking system. With an un-coated laser diode, it is necessary to use a method, such as the Pound-Drever-Hall control method, to maintain the lock between the master oscillator and the slave laser.

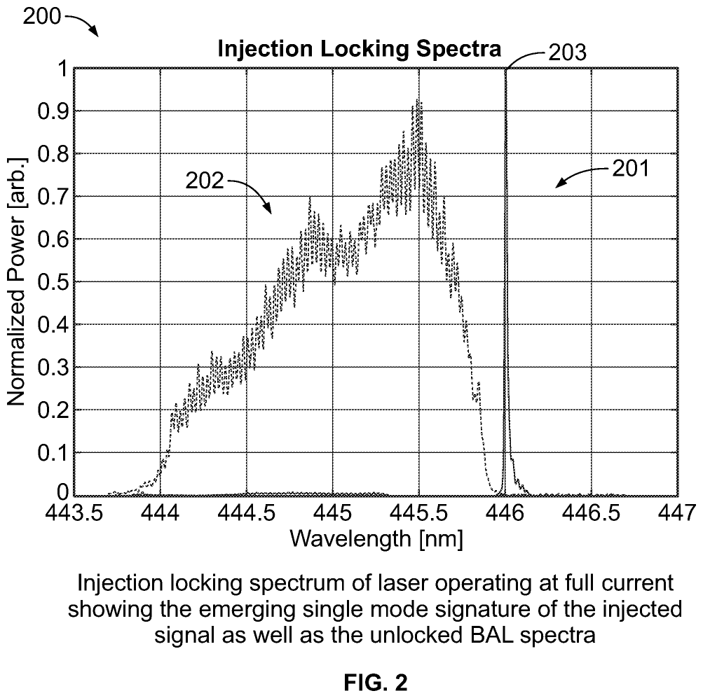

Turning to FIG. 2, there is shown a graph 200 of the normalized power (in arbitrary units) against wavelength for an injection locked BAL 201 and an unlocked BAL 202. The injection locked BAL output signal peak 203 at 446 nm is locked to master oscillator laser. The master oscillator laser is a single transverse mode laser diode capable of up to 100 mW of laser power that is locked to a single axial mode by an external Volume Bragg Grating (VBG). A VBG is a glass block with a varying index profile through the glass block in the direction of the laser beam that forms the grating. The grating has a reflection bandwidth that is sufficiently narrow that it only reflects one of the axial modes of the single transverse mode laser beam back into the front facet. This feedback causes the master oscillator to lock on a single axial mode. The drive current of the master oscillator and the temperature of the master oscillator are precisely controlled to maintain this lock. The output of the master oscillator external cavity system is transmitted through a Faraday isolator before being injected into another laser to prevent feedback from the external laser from disrupting the master oscillator lock. The degree of isolation required to prevent the master oscillator from being disrupted is typically 50-60 dB.

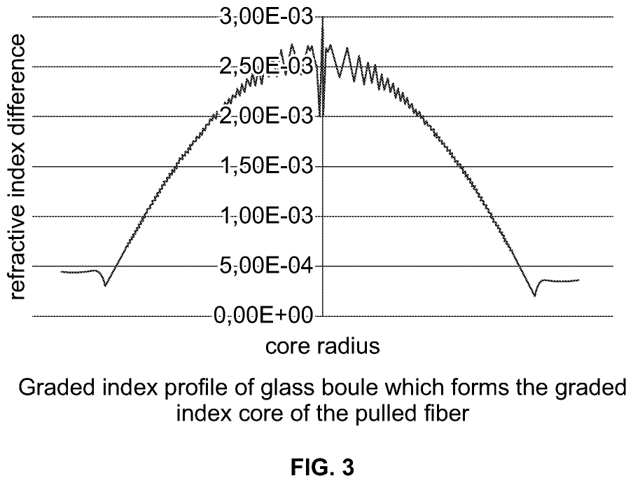

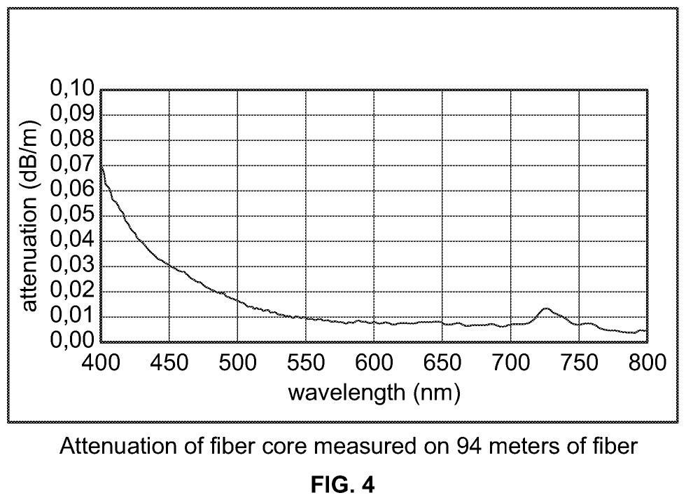

One or more multi-mode visible laser diodes can be simultaneously injection locked to create a high-power pump source that can be spatially combined as well as polarization combined and then launched into SBS optical fiber with the graded index profile shown in FIG. 3 surrounded by a higher NA (NA-0.2) region that can confine the low brightness pump source. This is a custom graded index fiber doped with phosphorous because germanium has a large absorption cross section at the preferred wavelengths of 440 nm to 460 nm and in particular at 450 nm. The losses for this fiber are less than 30 dB/km at 450 nm (FIG. 4), which is substantially lower than the SBS gain that can be created.

The phosphorous (P) doped fiber, for example of the type shown in FIGS. 3 and 4, operated as a SBS laser when injected by the narrow linewidth pump laser (3 MHz). Oscillation was achieved because the linewidth of the pump laser was narrower than the gain bandwidth (10 MHz) of the Brillion gain and had sufficient gain to overcome the losses in the fiber (FIG. 4) which resulted in laser oscillation. The SBS laser can be made to lase when the pump laser is coupled into either the outer step index core or the graded index core with higher lasing threshold for the outer core case due to the lower intensity of the pump laser. The master oscillator as already discussed, is a 1000 mW single transverse mode laser with a near diffraction limited beam divergence as is typical of a M²˜1 laser beam. The SBS laser produced a blue, 450 nm laser beam oscillating on the single transverse mode with an M² of <1.5 and a mode diameter of 10 mm. This corresponds to a beam parameter product of <0.2 mm-mrad. The laser which achieved threshold is believed to be the first successful demonstration of a blue laser diode pumped Visible Brillouin Laser.

The amount of phosphorous dopant in the fused silica fiber for embodiments of the present SBS lasers, using fuses silica fibers and doped graded index cores, and can have dopant amounts, e.g., P, from 1% mole to 20% mole P, from 1% to 5% mole, 1% to 15% mole, 5% to 25% mole, 2% to 5% mole, 1% to 10% mole, 5% to 12% mole, greater than 1% mole, greater than 2% mole, and greater than 5% mole. It being understood that this amount of dopant, e.g., P, is the total amount based on the fused silica, and that dopant is distributed according to the graded index profile achieved, for example as shown in FIG. 3. The dopant may also be used to create a step index core, however the step index core will have to be substantially smaller, than that shown in FIG. 3, to support the single mode at 450 nm. The outer step index core consists of a fused silica region surrounded by a fluorine doped region. The fluorine (F) doped region can have fluorine dopant amounts of 10% to 20% mole, greater than 8% mole, 10% mole and greater, 10% to 15% mole, 12% mole and greater, 12% to 15% and 15% to 20% mole, depending on the step index desired. These fibers can have a 0.2 NA cladding area. The fiber may also be constructed with just the graded index core that is 10 mm, or 20 mm or 60 mm or smaller or larger, surrounded by a fused silica clad for the purposed of mechanical support of the graded index core.

The larger graded index core, for example as shown in FIG. 3, of a step index fiber, (e.g., graded P doped core with outer F doped area providing a step index) allows the efficient coupling of the multi-transverse mode, single axial mode visible laser diode sources into this fiber. The embedded graded index portion of the fiber has a preferred LP₀₁ mode that is approximately 10 microns in diameter. The SBS process, will produce the brightness enhancement and oscillate on the lowest order transverse mode of the fiber, which is the LP₀₁ mode. This brightness enhancement has been observed between the below threshold condition and the above threshold condition.

In general, examples of embodiments the fiber used in the present SBS laser systems can be: a graded index core fiber; a graded index core fiber with an acrylate or similar low index material to create a high numerical aperture (NA)≤0.48 for accepting optical radiation; a graded index core embedded within a larger diameter step index core with a fluorine outer clad to create a pump core with an NA of 0.22 or less; a graded index cored embedded in a step index core with an acrylate or similar low index material coating the outside of the step index core to create a high numerical aperture ≤0.48 for accepting optical radiation; and combinations and variations of these. Examples of preferred embodiments of such fibers, for use in the present SBS laser systems, are disclosed and taught in U.S. Pat. No. 10,634,842, the entire disclosure of which is incorporated herein by reference.

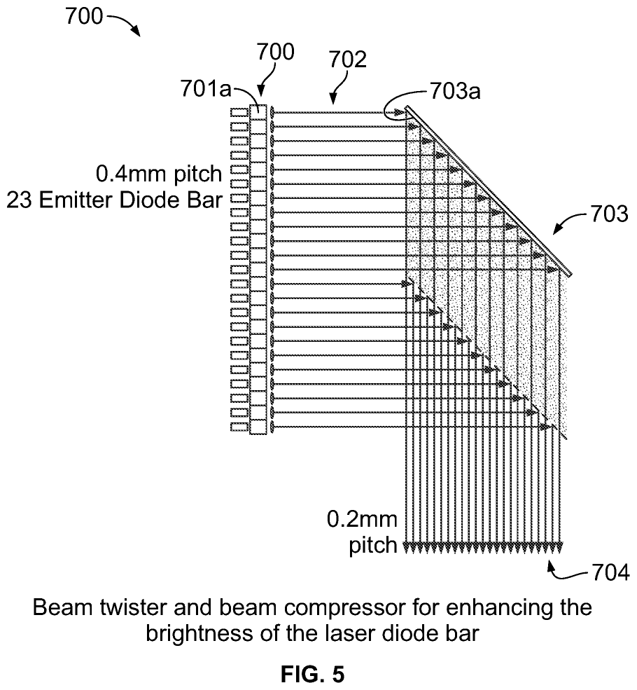

In order to couple the pump light into the larger core surrounding the graded index core of the SBS fiber the beam parameter product (BPP) of the pump laser must be less than that of the numerical aperture—radius product or acceptance BPP of the outer step index core. In the embodiment where the pump is an injection locked laser diode bar the bar BPP is kept below the acceptance BPP of the fiber by methods such as folding and compression of the emitters. One such embodiment is a beam twister and compressor assembly. Turning to FIG. 5 there is shown a beam twister and compressor assembly 700. The assembly 700 has a diode bar 701 having 23 diodes, e.g., 701a. The spacing or pitch of each emitter is 4 mm. Each emitter beam from the bar 700 enters into an optics assembly 702, which a pair of cylindrical lenses orientated such as to collimate the fast axis and slow axis of the laser diode. The slow axis cylindrical lenses can tilted at 45 degrees which is called a beam twister. The tilted cylindrical lenses create a 2× the beam rotation angle so the final output of each emitter is rotated by 90 degrees. There are other methods by which to achieve beam twisting including stepped mirrors and prisms. Following, the beam twister the output of the bar is sent into a prism compressor 703 where one half of the bar is reflected from a High Reflection (HR) or Total Internal Reflection (TIR) surface 703a internal to the prism 703 and the second half of the bar is reflected by a patterned mirror. This interdigitates each beamlet with the beamlet from the other half of the bar and minimizes the unused space between the emitters; and thus provide a beam spacing of 0.2 mm for the emitter beams from bar 701.

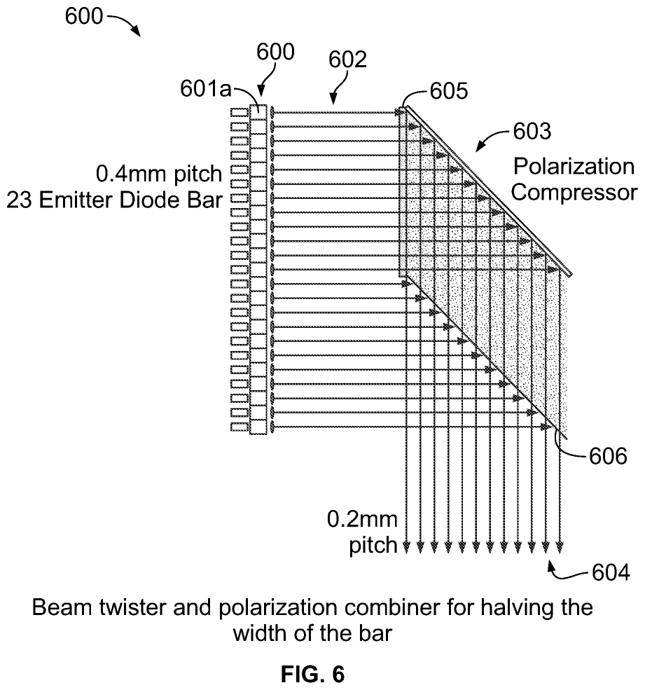

Turning to FIG. 6, there is shown an embodiment of a beam twister and compressor assembly 600. The assembly 600 has a diode bar 601 having 23 emitters, e.g., 601a, each spaced 0.4 mm apart. Each emitter beam from the bar 600 enters into an optics assembly 602, (e.g., a beam twister) where each beam is collimated and rotated around its axis. One half of the beams from the beam twister passes through a ½ waveplate 605 rotating the beam's polarization 90 deg. before reflecting on an HR or TIR surface 603a of the prism 603 (e.g., a polarization compressor). The other half of the beams from the bar reflects off the lower section of the prism where a polarization combining coating 606 is applied. The rotated half of the bar is now p polarized light and transmits through the coating 606 while the beams coming directly from the bar are s-polarized light, resulting in the p and s-polarized light now being co-linear. The resulting beams which consist of both p and s polarized light, 604 leave the assembly 600 with a spacing of 0.2 mm but an overall emission width of only 5 mm thus increasing the brightness of the laser diode bar source.

Laser diode beam parameter product or brightness is defined as the product of the beam divergence of the laser and the output aperture of the laser. For the laser diode bar in FIG. 6, the individual beams may have a beam parameter product of 3 mm-mrad but the source must take into account the entire extent of the bar. The bar itself would have a BPP of 3 mrad*10 mm or 30 mm-mrad. The embodiments of FIGS. 5 and 6 provide examples of way to effectively decrease the width of the bar from 10 mm to 5 mm, thus improving the BPP to 15 mm-mrad.

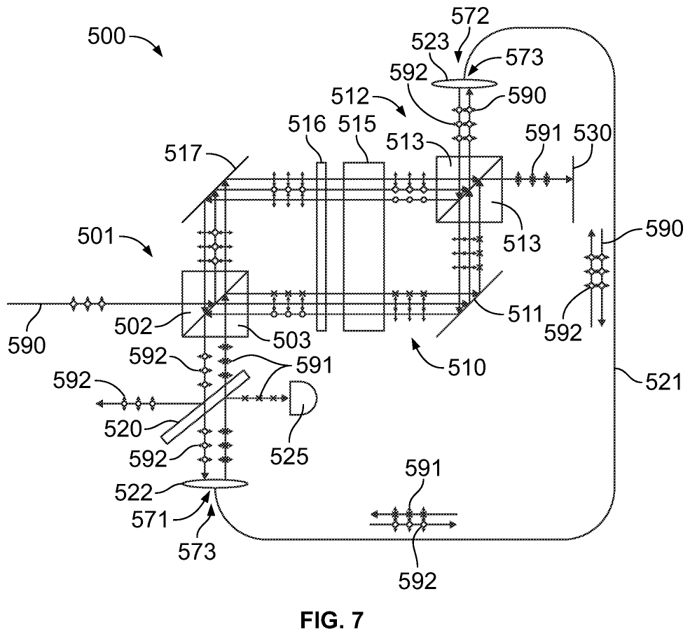

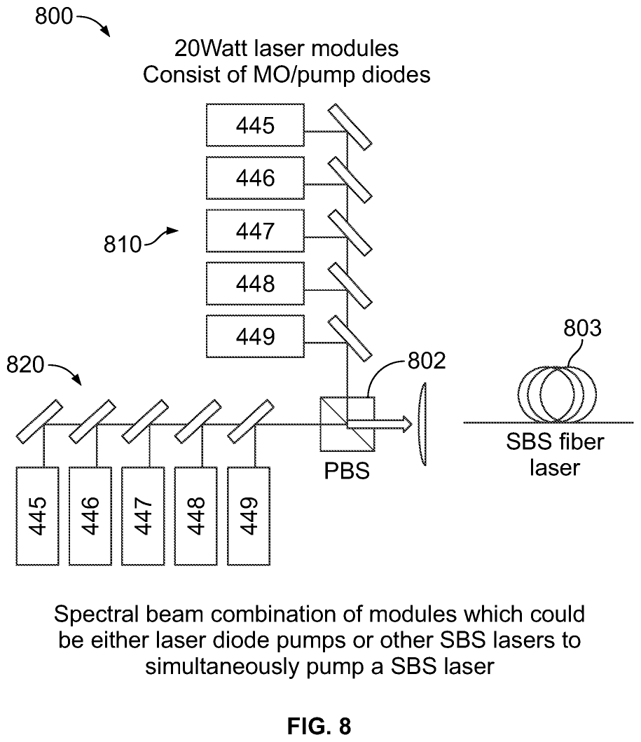

Turning to FIG. 7 there is shown a schematic of an example of a visible, e.g., blue SBS laser system. The blue SBS laser system 500 has a first assembly 501, that has port one (502), and port two (513). Port one (502) receives the pump light from the visible pump lasers (not shown). Embodiments of the system 500 can receive pump light from 1 or more, 2 or more, 3 or more, 4 or more 10 or more, 2 to 10, 10 to 100, and more, visible pump lasers. The visible pump lasers can be for example blue diodes lasers. The pump lasers may have a linewidth of <10 MHz when pumping a fused silica fiber, or may be a spectral beam combination of multiple pump lasers spaced 1 nm apart each with a linewidth of <10 MHz. For the case of all the pump lasers having the same linewidth, the input to the fiber is limited to a pump source that meets the input BPP for the fiber of 6.6 mm-mrad. The pump sources shown in FIGS. 5 and 6 are greater than the BPP so additional beam manipulation in the axis perpendicular to the page must be used to match the input BPP. The second case of scaling with bars that are spectrally beam combined means that many laser diode bars can be launched into the fiber to create a wider bandwidth output beam as shown for example in FIG. 8. A consideration regarding this approach is the finite bandwidth of the waveplates used in the circulator which could be 10 nm or 10 laser diode bars, in a single polarization and 20 laser diodes in both polarizations combined in the Polarization Beam Splitting cube (802) shown in FIG. 8.

In the system 500, the pump light 590 from the pump lasers is injected into port one (502). From port one (502) the pump laser beam 590 enters into circulator 510, which is made up of HR mirror 511, assembly 512, Faraday rotator 515, a half wave plate 516, an HR mirror 517 and assembly 501. Assembly 501 has port one (502) and port four (503). Assembly 512 has port two (513) and port three (514). The system 500 also has an output coupler 520, a visible step index fused silica fiber SBS laser 521, a fiber coupling lens 522, a fiber coupling lens 523, a photodiode monitor 525 and a beam dump 530. The ensemble of visible pump lasers (n>0) provides pump light 590 that is injected into the laser cavity 521 through a circulator 510 that can be either polarization sensitive or polarization insensitive. The pump light is injected into port one (502), and the SBS which produces backward traveling SBS light 592, exits the circulator 510 through port four (503). An output coupler 520 is used at the exit of port four (503) to extract the power from the cavity 592. The output coupler 520 may be partially transmissive to allow some of the backward propagating light to be reinjected into the optical fiber 521 by lens 522 to create a uni-directional ring laser oscillator. In this way only the backward propagating SBS light 592 undergoes gain with 520 having an optical coating that reflects the depleted pump 590 light and the second stoke light 591 into a beam dump and out of the cavity. The fiber 521 could also have a fiber Bragg grating at the entrance that can serve as an output coupler and the circulator can be removed from the cavity. However, since the fiber is doped with phosphorous it is not photosensitive such as is the case with a germanium doped optical fiber. Therefore, the process for writing a grating in the fiber is more complex and requires a point by point writing of the grating using a femtosecond laser to disorientate the core material and change its index. The last parts of the resonator are the endcaps 571, 572 on the optical fiber 521 and the cladding mode strippers 573, 574. These components provide an efficient launch of the pump power and the long-term reliability of the visible fiber laser. One of the key elements of reliability that has to be considered is the gettering of contaminates in the high intensity regions of the optical fiber. Both carbon and siloxanes are a serious problem at these wavelengths, so the endcaps have to be sufficiently large to reduce the power density at the face of the endcap/fiber to below the threshold for gettering these contaminants.

In general embodiments of the present systems and lasers take a pump source laser beam from one or more pump laser sources, such as diode lasers operating in the visible and preferable the blue wavelength range with both polarizations states present due to the brightness enhancement methods as shown in FIG. 6. The pump laser beams are locked to a narrow linewidth, and injected into a circulator assembly that separates the forward propagating light 590 from the backward propagating SBS light 592 in the optical fiber. The circulator can be either polarization dependent or polarization independent which is what is shown in FIG. 5. The forward propagating light from the pump lasers 590 enters the circulator 510 at the first polarization beam splitter that is located in assembly 501 and which forms part of port one (502). The s-polarized light is directed to mirror 517, the p-polarized light passes directly through the half waveplate 516, followed by the Faraday rotator 515 and after mirror 510 pass through 514-513 to exit port 2 513. The s-polarized light reflects off of mirror 517, passes through half wave plate 516 and Faraday rotator 515, the forward propagating light is directed to polarization beam splitter that is located in assembly 512 and which forms a part of port two (513) where it exits the circulator 510. The power exiting port 2 now consists of both p and s polarization light and is coupled into the fiber 521 by the lens assembly 523. The ends of the fiber 521 may be prepared by a simple cleave, an AR coating on the fiber face, an angle cleave to reduce back-reflections or a glass block fused onto the fiber to decrease the power density on the input surface of the optical assembly. The forward pump power 590 propagating into the fiber 521 is converted into the single mode, single frequency light that is propagating backwards 592 by the SBS phenomenon. The backward propagating light 592 enters the assembly 512 through port three (513) by way of a polarization beam splitting cube. The p-polarized light is transmitted by 512 and is reflected by mirror 511, passes through Faraday rotator 515, half waveplate 516, is now s-polarized light and is reflected by the coating in the polarization beam splitter cube assembly 501 and exits port 503. The s-polarized light incident on 513 is reflected and, and passes through the Faraday rotator 515, and half waveplate 516, and is now p-polarized light as it enters assembly 501 and is transmitted by the polarization beam splitting cube out port four 503. The beam can be extracted at this point or reinjected into the optical fiber to form a ring cavity through the lens 522. Undepleted pump light or second stokes 591 after passing through the fiber 521 is reflected by the mirror 520 to the beam dump 525. Any pump light or second stokes passing through the mirror 520 would be transmitted by assembly 512 out port three 514 to the beam dump 530.

In embodiments the Faraday rotator can be split into multiple components for high power applications.

The embodiment of a Spectral beam combination system 800 to provide a pump laser beam 890 is shown in FIG. 8. In that system 800, two sets 810, 820, of five 20 W laser modules have wavelengths of 445 nm, 446 nm, 447 nm, 448 nm and 449 nm are combined at polarizing beam splitter 802, for injecting into an SBS fiber laser 803 in the manner described in FIG. 7 through port one 502. The number of wavelengths that can be used is limited only by the bandwidth of the circulator or the efficiency of the dichroic combination method and can be any number of 5, 10, 20, 30 or more, 100 or less or more Dichroic combination may be accomplished with edge filters, bandpass filters, etalons, lyot filters, gratings, VBGs, or prisms.

The SBS fiber laser in the embodiment of FIG. 7 was 12 m long and was the fiber described in FIGS. 3 and 4. Embodiments of the present inventions can have SBS fiber laser configurations that are specific for the wavelength range to be oscillated. For example, the fiber of the embodiment of FIG. 7 has a 40 μm graded index core which supports a 10 μm LP₀₁ mode at 440 nm to 460 nm embedded in a fused silica region that extends the diameter of the core from 40 μm to 60 μm. The fused silica cores is then surrounded by a fluorine doped fused silica region to create a step index with a numerical aperture of 0.2. This fiber design can be described as a graded index core surrounded by a pump clad or as a graded index core embedded in a step index core. The pump clad can be either smaller, down to near the diameter of the LP₀₁ mode or much larger up to 100 μm. However, the larger the core, the more difficult the pump mode mixing, the lower the core gain and the longer the fiber that is needed to achieve lasing. Longer fibers are more susceptible to the onset of second stokes, so shorter fiber (<10 m) are preferred to avoid second stokes generation. Second stokes may lead to chaotic beam and output power behavior.

The Stimulated Brillouin Scattering characteristics (e.g., Brillion gain or gB), for various media is listed in Table 1, which lists the gain bandwidth and gain coefficient for a variety of bulk materials. SBS can be observed in many medium including gases, liquids and solids. In the preferred embodiment, the optical fiber is made from fused silica (SiO₂), however, many other options are possible including hollow fibers filled with the liquid or gas substances listed in Table 1. It should be noted that the Brillouin gain in fiber form exhibits slightly different parameters as shown in Table 2.

TABLE 1

| | Laser | | | | | |
|---|---|---|---|---|---|---|
| | wave- | | | | | |
| | length | Frequency | Δv | T_{B} | g_{B}^{e} | g_{B}^{a}/α |
| Substance | (nm) | shift (Ghz) | (MHz) | (ns) | (cm/GW) | (cm/GW)* |
| Liquid | | | | | | |
| Acetone | 532 | 5.93 | 361 | 0.44 | 12.9 | 22 |
| Benzene | 532 | 8.33 | 515 | 0.31 | 12.3 | 24 |
| CS₂ | 532 | 7.7 | 120 | 1.9 | 130 | 20 |
| CCl₄ | 532 | 5.72 | 890 | 0.18 | 8.77 | 13 |
| Chloroform | 532 | 5.75 | 635 | 0.25 | 11.7 | |
| Ethanol | 532 | 5.91 | 546 | 0.29 | 12* | 10 |
| Methanol | 532 | 5.47 | 325 | 0.49 | 10.6 | 13 |
| Water | 532 | 7.4 | 607 | 0.26 | 2.94 | 0.8 |
| Gas | | | | | | |
| Xenon | 532 | 0.654 ± 0.024 | 98.1 ± 8.9 | 0.65 | 1.38 ± 0.19 | |
| (7599 torr) | | | | λₚ²P | | |
| SF₆(20 bar) | 1320 | 0.2 | | 35 | | |
| N₂(100 bar) | 1320 | 0.5 | | 30 | | |
| Solid | | | | | | |
| BK 7 | 532 | 34.65 ± 0.039 | 165.0 ± 8.6 | | 2.15 ± 0.21 | |
| CaF₂ | 532 | 37.164 ± 1.185 | 45.6 ± 8.8 | | 4.11 ± 0.65 | |
| Plexiglas | 532 | 15.687 ± 0.036 | 253.7 ± 12.6 | | | |
| SiO₂ | 488 | 35.6 | 156 | | 4,482 | |

TABLE 2

| | Transparency | gₒ | Γ_{B}/2π | v_{B} (GHz) |
|---|---|---|---|---|
| Material | Range (μm) | (cm/GW) | (MHz) | (@1550 nm) |
| Fused | 0.25-3.6 | 4.52 | 16 | 11 |
| Silica | | | | |
| CaF₂ | 0.13-10 | 4.11 | 45.6 | 37.1 |
| TeO₂ | 0.33-5 | 100 | 8.6 ± 2.4 | 11.4 ± 2.2 |
| As₂S₃ | 1-8 | 74 | 19 | 7.7 |
| Silicon | >1.2 | 0.24 | 320 | 40 |
| Diamond | >0.23 | 79 ± 12 | 11.9 ± 4.3 | 56 |

Preferred embodiments of the present the systems uses a custom fiber, as the SBS fiber laser, that combines a step index pump clad of 60 μm out diameter with a gradient index core that is 40 μm in diameter within the 60 μm step index core with the profile shown in FIG. 3 and supports many modes with the highest gain being for the 10 μm diameter LP₀₁ mode. The LP₀₁ which has the highest gain will lead to the lowest possible M² for the output beam.

Using the relationship in equation 1, it is possible to calculate the threshold for single pass Stimulated Brillouin.

gₕK(Pₜₕ/A_{eff})L_{eff}≅21 (Equation 1)

Using this relationship, the estimated threshold for SBS to be generated in a fiber that is 10 meters long, with a multi-mode clad of 60 microns and a graded index core that supports a 10 microns diameter single mode at 450 nm, is >5 Watts. Here g_{B}˜4.5 cm/GW, K is a constant dependent on polarization, 0.5 for unpolarized, A_{eff} is based on a single mode diameter of 10 μm and L_{eff} is given by equation 2.

L_{eff}=α⁻¹(1−exp[−αL]) (Equation 2)

The first observation of lasing in a simple linear cavity was at less than 600 mWatts of pump power injected directly into the graded index core and consistent with the gain predicted for the cladding pumping of 5 Watts. Laser was confirmed by blocking the cavity and observing the spectrum of the laser. When the back mirror in the cavity was blocked the spectral signature at 10 GHz (SBS mode) disappeared confirming that the Brillouin laser was indeed oscillating

In a preferred embodiment the Master Oscillator is a monolithic external cavity laser formed with a Volume Bragg Grating (VBG), an external grating in the Littrow configuration, and external grating in the Littman-Metcalf configuration, or a series of etalons. The chip on submount or TO-can packaged laser diode is AR coated on one face to allow for an external cavity to be formed and collimated with a high-quality aspheric lens or pair of cylindrical lenses. The diode always emits a single transverse mode, but several axial modes are present when free running. When the laser diode is placed in an external cavity with one of the filter elements described, all but one of the longitudinal modes are suppressed, and a single axial mode is allowed to oscillate and dominates the output of the external cavity laser diode. The wavelength of the Master Oscillator is tuned by the temperature, operating current, and/or VBG, grating or etalon alignment.

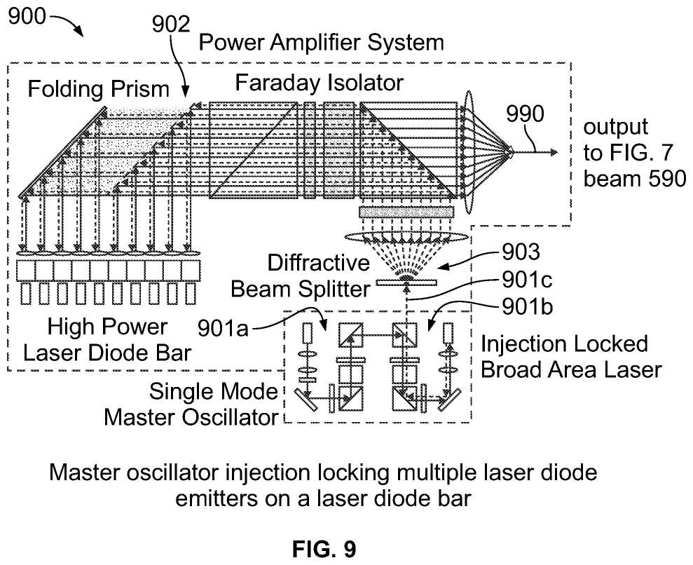

As shown in FIG. 9, to increase the pump power for SBS, a number (n>0) of BAL(s) or diode emitters as part of a laser diode bar are controlled via injection locking of the master oscillator to operate on a single axial mode and may additionally operate on a single transverse mode. Thus, turning to FIG. 9 there is shown a laser power amplifier system 900. The system 900 has a first laser assembly 901 that has single mode master oscillator assembly 901a that provides a laser beam to an injection locked Broad Area Laser (BAL) 901b, which provides a laser beam 901c to a diffractive beam splitter 903 that is in diode bar and beam integration system 902. The system 900 provides a laser beam 990, that can be used as a pump laser beam, for example as pump laser beam 590 in the embodiment of the system of FIG. 7. Further, in embodiments of systems, like the system 900, mode matching optics are inserted into the beam path between the master oscillator and the BAL(s) or diode bar(s) such that the beam waist and wavefront match that of the outgoing BAL(s) or diode bar(s). The master oscillator light is sent into the rejection port of an optical isolator such that it travels towards the BAL(s) or diode bar(s) but returning light from the BAL(s) or diode bar(s) transmits though the isolator exiting the output port, thus separating the two beams. When injection locking multiple (n>1) BALs or diode bar emitters the master oscillator beam passes through a diffractive optical element or passive beam splitter to generate a line or grid of beamlets equal to the number of BALs or diode bar emitters to be locked. The diffractive optical element splits the master oscillator into the number of beams required to inject each of the BALs, when combined with appropriate optics, the master oscillator is optimally matched to the outgoing beamlets and wavefronts of each emitter. When properly matched the coupling efficiency of the master oscillator into the individual laser diodes on the bar is maximized. When locking multiple (n>1) BALs or diode bar(s) the master oscillator may first be amplified by injection locking one (1) BAL in a pre-amplifier configuration to increase the power before splitting and injection locking additional BALs or diode bar(s).

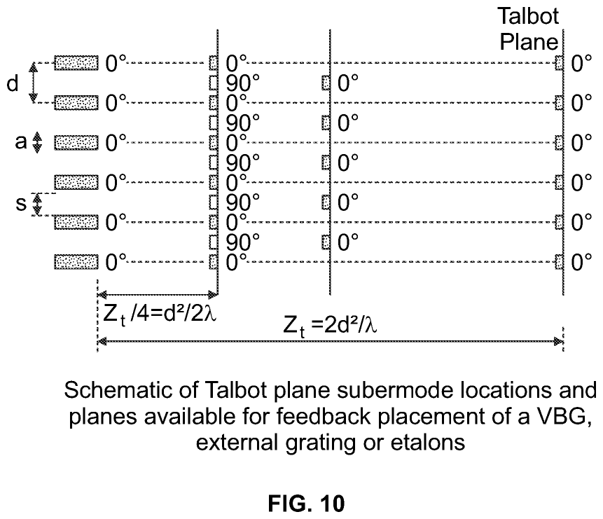

Another method to create a narrow linewidth pump array is to use an external cavity consisting of a VBG, an external grating in the Littrow configuration, and external grating in the Littman-Metcalf configuration, or etalons in a Talbot cavity. The etalons may be placed at a Talbot plane or at one-half (0.5) or one-quarter (0.25) of the distance to the Talbot plane with or without a phase conjugating element to shift the phase to match Talbot plate supermodes, as shown in FIG. 10. In this configuration the array of lasers may be imaged with magnification with a 4f or other imaging system to reduce the spacing of the emitters at the image plane and therefore decrease the Talbot distance and overall cavity length to increase the stability of the system. A waveguide consisting of 2 HR mirrors on the axis of the stacked BALs may surround the lasers to produce an image of an infinite array of emitters to improve the Talbot plane quality for emitters on the edges of the array.

The high-power multi-transverse but single-axial mode pump light generated from the BALs or diode bar(s) is injected into the custom fiber optic cable through a high-power optical circulator. The pump light enters the circulator in port 1 and is split by the first polarization beam splitter (PBS) into two arms. Each arm applies an identical polarization rotation by a half-waveplate followed or preceded by a Faraday Rotator which applies an opposite rotation of the polarization. The net shift in polarization for the pump is zero from the initial polarization of the split beam. When the two pump arms are combined on the second PBS they will recombine and exit via port two. A focusing lens brings the light to a focus into the 60 μm pump cladding of the fiber. Any pump light transmitted through the fiber is collimated at the other end of the fiber by a collimating lens and partially reflected by the output coupler to a monitor photodiode. This monitor photodiode provides a diagnostic port to separate the pump from the counter propagating SBS light and ensure that the pump is depleted and efficiently converted to single mode SBS. The remaining light transmitted through the output coupler enters the circulator in port four. The light is split by the first PBS but with opposite polarization directions compared with entering from port one. Again, the light passes through the half-waveplate and Faraday Rotator with a net polarization rotation of zero degrees. Due to the swapped polarization of each arm of the circulator, the pump will exit port three and be absorbed on a beam dump.

As the pump passes though the cladding of the fiber it will stimulate an SBS signal that propagates backwards along the length of the fiber. This SBS signal will re-enter the circulator via port four traveling the opposite direction as the pump. The SBS signal will be split by the PBS into the two arms of the circulator. The Faraday Rotator provides the same polarization rotation regardless of propagation direction, however the half-waveplate does not resulting in a net polarization shift of positive or negative 90 degrees. The two arms are then combined in the first PBS and exit the circulator via port three. A portion of the light is coupled out of the system by the output coupler which may be either a fixed non-polarizing beam splitter or a variable output coupler controlled via angle tuning of the output coupler. The transmitted SBS signal is fiber coupled into the 40 μm core of the fiber where it travels back to port two to form a ring cavity.

The SBS laser coupled from the output coupler may be coherently or incoherently combined with an ensemble of similar SBS lasers to produce a single high brightness beam. Coherently combining the SBS lasers requires the central mode to be polarized which can be accomplished by adding stress rods to the fiber design. The combination of multiple SBS lasers is straight forward because of the long coherent length produced by each laser source. The fiber laser outputs can be individually collimated and bundled to create an optical phased array. The output of the optical phased array can be monitored with a wavefront monitor either locally or remotely and the phase of each leg can be adjusted by changing the length of each fiber until a single central lobe is formed in the far-field. The far-field control algorithm can be a hill climbing servo loop, a multi-dither servo loop, a neural network or Artificial Intelligence control loop.

An incoherent combination of SBS lasers can be similar to FIG. 8. In the preferred embodiment a number (n>1) of similar SBS lasers are produced with each Master Oscillator tuned to a different wavelength. The output of each beam is incoherently combined with dichroic mirrors or a grating to generate a single beam of high output power while maintaining the beam quality of the initial beams.

Prior to launching into a longer process fiber the spectrum of the SBS laser will need to be broadened or the fiber modified to prevent further SBS or other nonlinear effects as it travels down the fiber. The laser can be broadened with an Acoustic Optic Modulator, and Electro-Optic Modulator, or a PZT for stretching the fiber and causing phase modulation, or a vibrating mirror to phase modulate the beam such that the effective beam linewidth is broadened. This may be implemented before or after coherently or incoherently combining multiple (n>1) similar SBS lasers as previously described.

It is noted that there is no requirement to provide or address the theory underlying the novel and groundbreaking performance or other beneficial features and properties that are the subject of, or associated with, embodiments of the present inventions. Nevertheless, various theories are provided in this specification to further advance the art in this important area, and in particular in the important area of lasers, laser processing and laser applications. These theories put forth in this specification, and unless expressly stated otherwise, in no way limit, restrict or narrow the scope of protection to be afforded the claimed inventions. These theories many not be required or practiced to utilize the present inventions. It is further understood that the present inventions may lead to new, and heretofore unknown theories to explain the operation, function and features of embodiments of the methods, articles, materials, devices and system of the present inventions; and such later developed theories shall not limit the scope of protection afforded the present inventions.

The various embodiments of lasers, diodes, arrays, modules, assemblies, activities and operations set forth in this specification may be used in the above identified fields and in various other fields. Additionally, these embodiments, for example, may be used with: existing lasers, additive manufacturing systems, operations and activities as well as other existing equipment; future lasers, additive manufacturing systems operations and activities; and such items that may be modified, in-part, based on the teachings of this specification. Further, the various embodiments set forth in this specification may be used with each other in different and various combinations. Thus, for example, the configurations provided in the various embodiments of this specification may be used with each other; and the scope of protection afforded the present inventions should not be limited to a particular embodiment, configuration or arrangement that is set forth in a particular embodiment, example, or in an embodiment in a particular Figure.

The invention may be embodied in other forms than those specifically disclosed herein without departing from its spirit or essential characteristics. The described embodiments are to be considered in all respects only as illustrative and not restrictive.

1. A SBS visible wavelength SBS laser, the visible SBS laser comprising:
a. a first assembly comprising a plurality of laser diodes, and a beam integration system, whereby the first assembly is configured to provide a first laser beam;
b. a second assembly comprising a first port for receiving the first laser beam from the first assembly, a second port, a third port and a fourth port;
c. an optical fiber resonator comprising a medium, a graded index core, and configured to provide a Brillion gain;
d. wherein a first end of the optical fiber is associated the second port and a second end of the optical fiber is associate with the third port;
whereby the first end of the optical fiber receives the first laser beam in a forward propagating direction; whereby the optical fiber is configured to generate and propagate an SBS laser beam in a backward direction within the optical fiber resonator, thereby providing a backward propagating SBS laser beam; and whereby the optical fiber is configured to propagate an undepleted first laser beam in the forward direction;
e. the second end of the optical fiber configured to propagate the underplated first laser beam to port three of the second assembly;
f. port three of the second assembly configured to propagate the backward propagating SBS laser beam into the second end of the optical fiber resonator, out of the system as an output beam, or both;
g. the fourth port configured to prorogate the undepelated first laser beam out of the system.

2. The visible SBS laser of claim 1, wherein the first laser beam has a wavelength in the blue wavelength range and an input BPP; the output laser beam has a wavelength in the blue wavelength range and an output BPP, wherein the output BPP is improved over the input BBP by from 10× to 400×.

3. The visible SBS laser of claim 2, wherein the first assembly comprises a BAL; the second assembly comprises a Faraday rotator, a half wave plate and an HR mirror.

4. The visible SBS laser of claim 1, wherein the output laser beam is a single mode beam.

5. A visible wavelength SBS laser, the visible SBS laser comprising: a pump laser diode configured to operate at a wavelength between 380 nm and 700 nm; the pump laser diode in optical communication with an optical fiber resonator, and an optical junction; wherein the optical fiber resonator is configured to provide a Brillion gain; wherein the visible SBS laser is configured to generate and propagate an SBS laser beam.

6. The visible SBS laser of claim 5, wherein the pump laser comprises a plurality of laser diodes, wherein the plurality of laser diodes comprises one or more of multi-transverse laser diodes, a multi-transvers laser diode bar, transverse mode laser diodes, and a transverse mode laser diode bar; wherein the plurality of laser diodes has wavelengths between 380 nm and 700 nm.

7. The visible SBS laser of claim 5, wherein the SBS laser beam is a low M² beam of less than 10.

8. The visible SBS laser of claim 5, wherein the optical fiber resonator comprises a phosphorous doped graded index fiber.

9. The visible SBS laser of claim 5, wherein the optical fiber resonator comprises a phosphorous doped graded index fiber embedded in a step index core to enable low brightness laser sources to couple efficiently to the graded index core.

10. The visible SBS laser of claim 5, wherein the optical fiber resonator comprises a polarization preserving phosphorous doped graded index core to increase the SBS gain of the fiber resonator and maintain polarization during oscillation.

11. The visible SBS laser of claim 5, wherein the optical fiber resonator comprises a bulk SBS medium.

12. The visible SBS laser of claim 5, wherein the optical junction comprises a circulator to extract power from the resonator.

13. The visible SBS laser of claim 5, wherein the optical junction comprises a circulator to redirect power from the laser resonator.

14. The visible SBS laser of claim 5, comprising an etalon to allow a pump beam to transmit into a cavity while forming a linear cavity for the SBS laser with an anti-node of the etalon.

15. The visible SBS laser of claim 5, comprising an embedded fiber Bragg grating as an output coupler, a high reflector or both.

16. The visible SBS laser of claim 5, comprising one or more of an Acoustic Optic Modulator (AOM), and an Electro-Optic Modulator (EOM) such that the effective beam linewidth is broadened to allow transmission down a longer process fiber.

17. The visible SBS laser of claim 5, comprising one or more of a pzt for stretching the fiber and causing phase modulation, and a vibrating mirror to phase modulate the beam; such that the effective beam linewidth is broadened to allow transmission down a longer process fiber.

18. The visible SBS laser of claim 5, comprising a process fiber with periodic index variations longitudinally along the process fiber to suppress the SBS in the process fiber.

19. The visible SBS laser of claim 5, comprising a process fiber with strain or periodic strain longitudinally along the process fiber to suppress the SBS in the process fiber.

20. A visible wavelength SBS laser system, the system comprising a plurality of the visible SBS lasers of claim 1, claim 5, or both claims 1 and 5, wherein the SBS laser beams from the plurality of visible SBS lasers are combined to form a single SBS beam having an M² less than 10.

21. The system of claim 20, wherein the plurality of visible SBS lasers are incoherently combined using spatial or polarization, or spatial and polarization, combination methods.

22. The system of claim 20, wherein the plurality of visible SBS lasers are combined using dichroic filters to overlap the SBS laser beams.

23. The system of claim 20, wherein the plurality of visible SBS lasers are combined using VBGs to overlap the SBS laser beams.

24. The system of claim 20, wherein the plurality of visible SBS lasers are combined using gratings to overlap the SBS laser beams.

25. The system of claim 20, wherein the plurality of visible SBS lasers are combined using a Lyot filter to overlap the SBS laser beams.

26. The visible SBS laser of claim 6, where a linewidth of the laser diode pumps is narrowed by injection locking from a common Master Oscillator source.

27. The visible SBS laser of claim 6, where a linewidth of the laser diode pumps is narrowed by injection locking from a common Master Oscillator source that has been amplified by multiple broad area lasers where the multiple may be 1, 2 or more depending on the amount of power distributed to the pump laser diodes.

28. The visible SBS laser of claim 6, where a linewidth of the laser diode pumps is narrowed by injection locking from multiple Master Oscillator sources that are mutually coherent.

29. The visible SBS laser of claim 6, where a linewidth of the laser diode pumps is narrowed by a common VBG configured as an external mirror.

30. The visible SBS laser of claim 6, where a linewidth of the laser diode pumps is narrowed by a common transmission grating in Littrow in an external cavity.

31. The visible SBS laser of claim 6, where a linewidth of the laser diode pumps is narrowed by a common reflection grating in Littrow.

32. The visible SBS laser of claim 6, where a linewidth of the laser diode pumps is narrowed by reflection grating in a Litman-Metcalf external cavity.

33. The visible SBS laser of claim 6, where a linewidth of the laser diode pumps is narrowed by one or more of a common etalon or combination of etalons in an external cavity.

34. The visible SBS laser of claim 6, where a linewidth of the laser diode pumps is narrowed in a Talbot cavity using one or more of a mirror, VBG, grating, etalon or injection source.

35. The visible SBS laser of claim 6, where a linewidth of the laser diode pumps is controlled by a precision current source with noise <10 nAmps.

36. The visible SBS laser of claim 6, where a linewidth of the laser diode pumps is less than the SBS gain.

37. The visible SBS laser of claim 6, where a linewidth of the laser diode pumps is less than 16 GHz.

38. A method of using the visible SBS lasers of claim 1, claim 5, or both claims 1 and 5, the method comprising one or more of 3D printing, welding projection display, laser light shows, medical applications, a scanner, a scanner for remote welding, a scanner for remote 3D printing, laser communications, cutting, cutting underwater, and annealing semiconductor materials.

39-52. (canceled)
